(19) United States
(12) Patent Application Publication
(10) Pub. No.: US 2016/0277017 A1
(43) Pub. Date: Sep. 22, 2016

(54) SNUBBER CIRCUIT

(71) Applicant: FSP TECHNOLOGY INC., Taoyuan City (TW)

(72) Inventor: Kuo-Fan Lin, Taoyuan City (TW)

(21) Appl. No.: 15/166,236

(22) Filed: May 26, 2016

Related U.S. Application Data
(63) Continuation-in-part of application No. 13/612,867, filed on Sep. 13, 2012.
(60) Provisional application No. 61/682,319, filed on Aug. 13, 2012.
(60) Provisional application No. 61/533,796, filed on Sep. 13, 2011.

(30) Foreign Application Priority Data
Jan. 31, 2012 (TW) 101103040

(51) Int. Cl. H03K 17/081; H01L 21/56; H02M 1/34; H01L 23/00; H01L 23/31

(52) U.S. Cl. CPC H03K 17/08112; H01L 24/09; H01L 23/3114; H03K 17/08116; H03K 17/08104; H02M 1/34; H01L 24/32; H01L 24/73; H01L 24/17; H01L 24/85; H01L 21/565; H01L 2224/04042; H01L 2224/4816; H01L 2924/12035; H01L 2924/1205; H01L 2924/13055; H01L 2924/1305; H01L 2924/1206; H01L 2924/1207; H01L 2924/13063; H01L 2924/1301; H02M 2001/344; H01L 2924/1203; H01L 2224/48091; H01L 2224/48106; H01L 2224/48175; H01L 2224/32245; H01L 2224/73265; H01L 2224/16225; H01L 2224/16245; H01L 2224/1703

(57) ABSTRACT

A snubber circuit is provided. The snubber circuit includes a transistor structure and a first capacitor. The transistor structure includes a chip package and two pins. The chip package includes a transistor die and a molding compound encapsulating the transistor die. A first pin of the two pins is electrically connected to a first bonding pad and a second bonding pad of the transistor die, and a second pin of the two pins is electrically connected to a third bonding pad of the transistor die. The first pin or the second pin of the transistor structure is electrically connected to a terminal of the first capacitor.

### CROSS REFERENCE TO RELATED APPLICATIONS

This is a continuation-in-part of U.S. application Ser. No. 13/612,867 (filed on Sep. 13, 2012), which claims the benefit of U.S. provisional application No. 61/533,796 (filed on Sep. 13, 2011) and U.S. provisional application No. 61/682,319 (filed on Aug. 13, 2012). The entire contents of the related applications are included herein by reference.

### BACKGROUND OF THE INVENTION

1. Field of the Invention

The present invention relates to a snubber circuit, and more particularly, to a snubber circuit including a transistor structure with two pins and related packaging method thereof.

2. Description of the Prior Art

In recent years, due to the continued development of the technology of electronic circuits, the protection circuits of a variety of electrical/electronic components are widely implemented in many applications. In conventional protection circuits, for instance, a RCD snubber circuit 400 as shown in FIG. 22 is formed by making the resister R6 and the capacitor C12 connected in parallel, and then connected to the diode D11 in series. However, the RCD snubber circuit has disadvantages like the high energy loss, poor efficiency and high spike voltage value, so the use of conventional RCD snubber circuit could easily lead to the damage of the semiconductor elements. Therefore, there is a need for a novel electronic component which may replace diode D11 to enhance the circuit protection performance of the snubber circuit.

### SUMMARY OF THE INVENTION

An objective of the present invention is to provide a transistor structure and a related packaging method, which may be applied to a snubber circuit to protect components efficiently and improve efficiency.

An objective of the present invention is to provide a transistor structure and the related packaging method, which can simplify the process, reduce size, and increase the withstanding voltage.

An objective of the present invention is to provide a snubber structure which can protect components efficiently, recycle energy and improve efficiency.

To achieve the aforesaid objectives, the transistor structure of the present invention includes a chip package and two pins, wherein the chip package includes a transistor die and a molding compound encapsulating the transistor die; and a first pin of the pins is electrically connected to a first and a second bonding pads of the transistor die, and a second pin of the pins is electrically connected to a third bonding pad of the transistor die.

In accordance with the aforesaid transistor structure, the first pin or the second pin of the transistor structure is connected to a terminal of a capacitor, thereby forming a snubber circuit to be connected to an active component or a load in parallel.

In accordance with the aforesaid transistor structure, one terminal of the capacitor is further connected to one terminal of a zener diode, and another terminal of the capacitor is connected to another terminal of the zener diode, thereby forming a snubber circuit to be connected to an active component or a load in parallel.

In accordance with the aforesaid transistor structure, the first pin or the second pin is connected to a terminal of a resistor, and another terminal of the resistor is connected to a terminal of a capacitor, thereby forming a snubber circuit to be connected to an active component or a load in parallel.

In accordance with the aforesaid transistor structure, the active component is or is assembled by a Metal Oxide Semiconductor Field Effect Transistor (MOSFET), a diode, a Bipolar Junction Transistor (BJT), an Insulated Gate Bipolar Transistor (IGBT), a Static Induction Transistor (SIT), or a thyristor, and the load is or is assembled by an inductor, a resistor, or a capacitor.

In accordance with the aforesaid transistor structure, the transistor die is a BJT die.

In accordance with the aforesaid transistor structure, the first bonding pad of the transistor die is an emitter bonding pad, and the second bonding pad is a base bonding pad, and the third bonding pad is a collector bonding pad.

In accordance with the aforesaid transistor structure, the first bonding pad, the second bonding pad, and the third bonding pad is connected to the pins by way of wire bonding.

In accordance with the aforesaid transistor structure, the wire bonding is connected to the pins through three bonding wires respectively.

In accordance with the aforesaid transistor structure, the first bonding pad and the second bonding pad are electrically connected to each other, and one of the pins is connected to the first bonding pad or the second bonding pad through a bonding wire, and the third bonding pad is connected to another one of the pins through a bonding wire.

In accordance with the aforesaid transistor structure, the first bonding pad, the second bonding pad, and the third bonding pad are electrically connected to the pins by way of flip chip bonding.

In accordance with the aforesaid transistor structure, the chip package further comprises a die pad, and the transistor die is set on the die pad by an adhesion layer.

Therefore, one of the pins is electrically connected to a first bonding pad and a second bonding pad of the transistor die, and another one of the pins is electrically connected to a third bonding pad of the transistor die. The transistor structure may be applied in a snubber circuit, or the snubber circuit may be encapsulated in the two-pin transistor structure to connect an active component or a load in parallel to absorb spikes or noise generated by the active component while the active component is switching at a high frequency. Therefore, the packaging of the transistor structure could simplify the process, reduce size, increase the withstanding voltage, and improve the efficiency and reduce the spike voltage of the power supply of the snubber circuit.

According to an embodiment of the present invention, an exemplary snubber circuit is disclosed. The exemplary snubber circuit comprises a transistor structure and a first capacitor. The transistor structure comprises a chip package and two pins. The chip package comprises a transistor die and a molding compound encapsulating the transistor die. A first pin of the two pins is electrically connected to a first bonding pad and a second bonding pad of the transistor die, and a second pin of the two pins is electrically connected to a third bonding pad of the transistor die. The first pin or the second pin of the transistor structure is electrically connected to a terminal of the first capacitor.

It should be noted that the aforesaid general descriptions and the following embodiments are only for illustrative purposes, and do not limit the scope of the present invention.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1A is a diagram illustrating a transistor structure according to a first embodiment of the present invention.

FIG. 1B is a diagram illustrating a transistor structure according to a second embodiment of the present invention.

FIG. 1C is a diagram illustrating a transistor structure according to a third embodiment of the present invention.

FIG. 2A is a diagram illustrating a transistor die of the present invention which is a BJT die.

FIG. 2B is a diagram illustrating a transistor die of the present invention which is a BJT die.

FIG. 2C is a diagram illustrating a connection between a BJT die and a capacitor die of the present invention.

FIG. 2D is a diagram illustrating a connection between a BJT die, a capacitor die, and a zener diode of the present invention.

FIG. 3 is a diagram illustrating an exemplary snubber circuit according to an embodiment of the present invention.

FIG. 4 is a diagram illustrating an exemplary snubber circuit according to another embodiment of the present invention.

FIG. 5 is a sectional diagram illustrating the transistor structure electrically connected to pins and bonding pads by way of wire bonding according to an embodiment of the present invention.

FIG. 6 is a sectional diagram illustrating the transistor structure electrically connected to pins and bonding pads by way of wire bonding according to another embodiment of the present invention.

FIG. 7 is a sectional diagram illustrating the transistor structure electrically connected to pins and bonding pads by way of wire bonding according to another embodiment of the present invention.

FIG. 8 is a sectional diagram illustrating the transistor structure electrically connected to pins and bonding pads by way of wire bonding according to another embodiment of the present invention.

FIG. 9 is a sectional diagram illustrating the transistor structure electrically connected to pins and bonding pads by way of wire bonding according to another embodiment of the present invention.

FIG. 10 is a sectional diagram illustrating the transistor structure electrically connected to pins and bonding pads by way of flip chip bonding according to an embodiment of the present invention.

FIG. 11 is a sectional diagram illustrating the transistor structure electrically connected to pins and bonding pads by way of flip chip bonding according to another embodiment of the present invention.

FIG. 12A is a diagram illustrating an appearance of the transistor packaging according to an embodiment of the present invention.

FIG. 12B is a diagram illustrating an appearance of the transistor packaging according to another embodiment of the present invention.

FIG. 12C is a diagram illustrating an appearance of the transistor packaging according to another embodiment of the present invention.

FIG. 12D is a diagram illustrating an appearance of the transistor packaging according to another embodiment of the present invention.

FIG. 13A is a diagram illustrating an appearance of the transistor packaging according to another embodiment of the present invention.

FIG. 13B is a diagram illustrating an appearance of the transistor packaging according to another embodiment of the present invention.

FIG. 13C is a diagram illustrating an appearance of the transistor packaging according to another embodiment of the present invention.

FIG. 13D is a diagram illustrating an appearance of the transistor packaging according to another embodiment of the present invention.

FIG. 14 is a snubber circuit applied to the transistor structure of the present invention.

FIG. 15 is a flowchart illustrating a transistor packaging method according to a first embodiment of the present invention.

FIG. 16 is a flowchart illustrating a transistor packaging method according to a second embodiment of the present invention.

FIG. 17 is a flowchart illustrating a transistor packaging method according to a third embodiment of the present invention.

FIG. 18 is a flowchart illustrating a transistor packaging method according to a fourth embodiment of the present invention.

FIG. 19 is a flowchart illustrating a transistor packaging method according to a fifth embodiment of the present invention.

FIG. 20 is a flowchart illustrating a transistor packaging method according to a sixth embodiment of the present invention.

FIG. 21 is a flow chart of an exemplary method for forming a snubber circuit according to an embodiment of the present invention.

FIG. 22 is a diagram illustrating a conventional snubber circuit.

### DETAILED DESCRIPTION

Detailed description of technical features and embodiments of the present invention would be obtained in the following description with reference to accompanying figures.

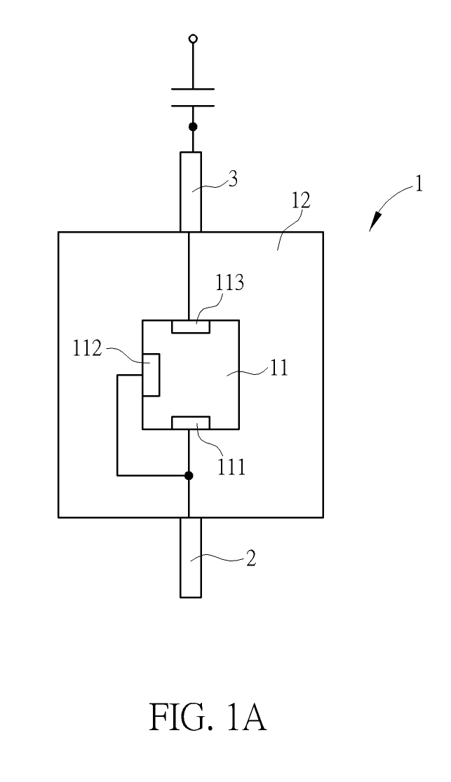

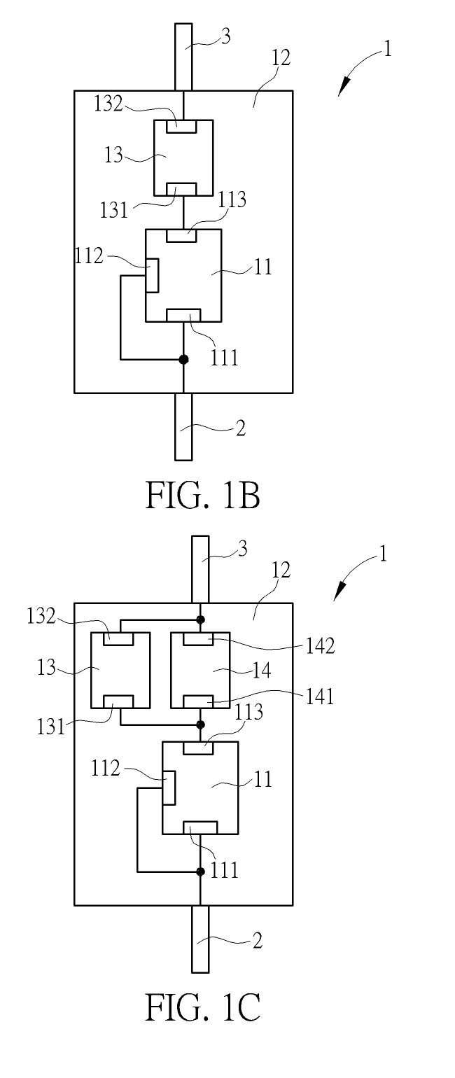

Please refer to FIG. 1A, which is a diagram illustrating a transistor structure according to a first embodiment of the present invention. The transistor structure of the present invention includes a chip package 1 and two pins 2 and 3, wherein the chip package 1 includes a transistor die 11 and a molding compound 12 encapsulating the transistor die 11; and the pin 2 is electrically connected to a first bonding pad 111 and a second bonding pad 112 of the transistor die 11, and the pin 3 is electrically connected to a third bonding pad 113 of the transistor die 11.

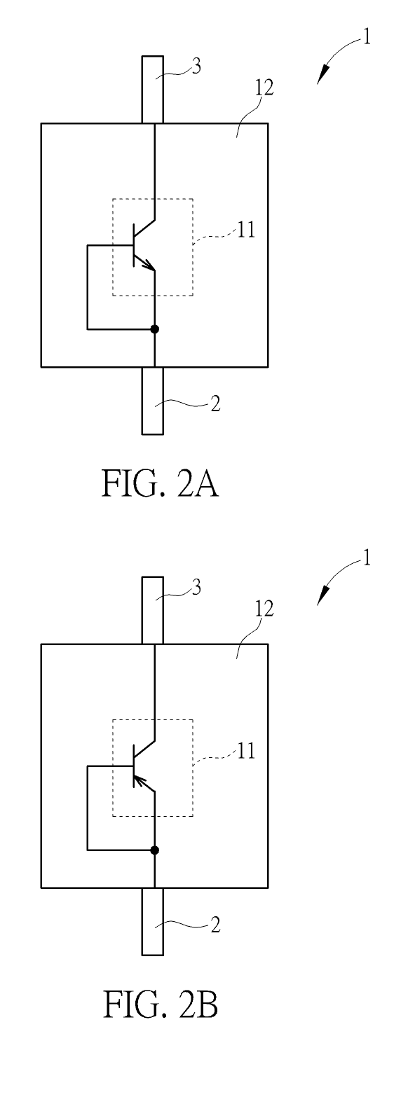

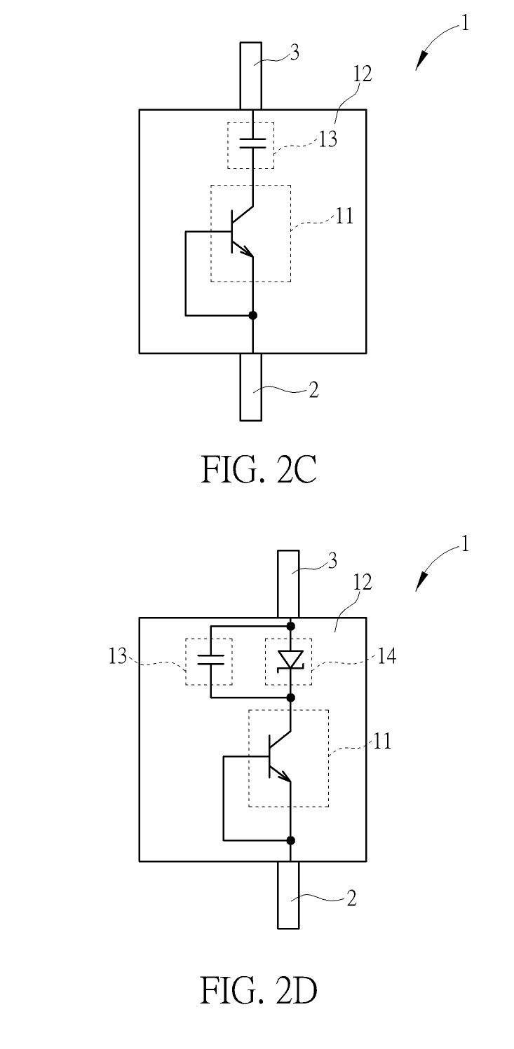

The transistor die 11 of the transistor structure of the present invention is a Bipolar Junction Transistor (BJT) die, and the BJT may be an NPN type BJT die or a PNP type BJT die. Please refer to FIG. 1A in conjunction with FIG. 2A and FIG. 2B. The first bonding pad 111 of the transistor die 11 is an emitter bonding pad, and the second bonding pad 112 is a base bonding pad, and the third bonding pad 113 is a collector bonding pad, wherein the emitter bonding pad and the base bonding pad are electrically connected to the pin 2, and the collector bonding pad is electrically connected to the pin 3.

Thus, base and emitter of the BJT of this embodiment are conductive, and the transistor structure has characteristics like fast turn-on, long storage time, switching smoothly, and small base-collector junction capacitance C_{bc} according to at least one junction characteristic between the base and the collector of the BJT die. The transistor structure therefore may be used as a fast diode for a snubber circuit.

The snubber circuit may have one of the following structures: (1) a CB snubber circuit, implemented by connecting the pin 2 or the pin 3 of this embodiment to a terminal of a capacitor to thereby form a snubber circuit to be connected to an active component or a load in parallel; (2) a ZCB snubber circuit, implemented by connecting the pin 2 or the pin 3 of the transistor structure Q to a terminal of a capacitor C and a terminal of a zener diode D, and connecting another terminal of the capacitor C to another terminal of the zener diode D to thereby form a snubber circuit (as shown in FIG. 14) to be connected to an active component or a load in parallel (not shown); (3) an RCB snubber circuit, implemented by connecting the pin 2 or the pin 3 of the transistor structure of this embodiment to a terminal of a resistor and connecting another terminal of the resistor to a terminal of a capacitor to thereby form a snubber circuit to be connected to an active component or a load in parallel (not shown).

The active component is or is assembled by a Metal Oxide Semiconductor Field Effect Transistor (MOSFET), a diode, a Bipolar Junction Transistor (BJT), an Insulated Gate Bipolar Transistor (IGBT), a Static Induction Transistor (SIT), or a thyristor. The load is or is assembled by an inductor, a resistor, or a capacitor. For example, the snubber circuit is connected to a primary side of a transformer of a switching power supply in parallel and then connected to a MOSFET in series; or the snubber circuit is connected to a secondary side of a transformer of a switching power supply and a MOSFET in parallel; or the snubber circuit is connected to a MOSFET in parallel and then connected to a secondary side of a transformer of a switching power supply in series to absorb spikes or noise generated by the active component while the active component is switching at the high frequency. In this way, the spikes generated by the active component could be reduced and thus the efficiency is improved.

Please refer to following Table 1 and Table 2. Table 1 is an experimental testing report of a conventional RCD snubber circuit, and Table 2 is an experimental testing report of the transistor structure applied to the above mentioned ROB snubber circuit according to this embodiment, where the RCD snubber circuit and the RCB snubber circuit are both connected to a primary side of a transformer in parallel and then connected to a MOSFET in series. According to the testing result of Table 1 and Table 2, the efficiency of the RCB snubber circuit of this embodiment is proved to be better than the efficiency of the conventional RCD snubber circuit based on the experiment, especially when the snubber circuit is electrically connected to a light load. The light load indicates that the percent of rated load is smaller or equal to 20%, namely the load accounts for less than 20%, for instance, the percent of rated load is 1%-20%; the efficiency of Table 2 (RCB snubber circuit) is 10.57% (57.48%-68.59%) higher than the efficiency of Table 1 (RCD snubber circuit) at a condition that the percent of rated load of both Table 1 and Table 2 is 1%. And the efficiency of Table 2 is 1.23% (88.22%-89.45%) higher than the efficiency of Table 1 at a condition that the percent of rated load of both Table 1 and Table 2 is 20%.

TABLE 1

| Input_Voltage(V) = 90 Vac | Load_{—} | | | | | | | | | | | |
|---|---|---|---|---|---|---|---|---|---|---|---|---|
| Percent_of_Rated_Load | 1% | 2% | 3% | 4% | 5% | 6% | 7% | 20% | 25% | 50% | 75% | 100% |
| Output_Current (A) | 0.013 | 0.0259 | 0.0516 | 0.0777 | 0.1038 | 0.1298 | 0.1557 | 0.4608 | 0.576 | 1.158 | 1.727 | 2.302 |
| Output_Voltage (V) | 19.265 | 19.262 | 19.26 | 19.257 | 19.257 | 19.257 | 19.255 | 19.24 | 19.232 | 19.2 | 19.19 | 19.14 |
| Efficiency_(%) | 57.84% | 68.15% | 74.17% | 77.93% | 80.60% | 81.15% | 83.05% | 88.22% | 88.48% | 89.15% | 88.61% | 87.94% |

| | | |
|---|---|---|
| Average_Efficiency_(%) | — | 88.55% |

TABLE 2

| Input_Voltage(V) = 90 Vac | Load_{—} | | | | | | | | | | | |
|---|---|---|---|---|---|---|---|---|---|---|---|---|
| Percent_of_Rated_Load | 1% | 2% | 3% | 4% | 5% | 6% | 7% | 20% | 25% | 50% | 75% | 100% |
| Output_Current (A) | 0.013 | 0.0256 | 0.0516 | 0.0777 | 0.1038 | 0.1298 | 0.1558 | 0.46 | 0.575 | 1.1506 | 1.7262 | 2.303 |
| Output_Voltage (V) | 19.257 | 19.257 | 19.255 | 19.252 | 19.25 | 19.25 | 10.247 | 19.232 | 19.227 | 19.192 | 19.16 | 19.13 |
| Efficiency_(%) | 68.59% | 78.5% | 83.42% | 84.99% | 86.13% | 86.76% | 87.68% | 89.45% | 89.52% | 89.04% | 88.67% | 88.11% |

| | | |
|---|---|---|
| Average_Efficiency_(%) | — | 88.84% |

Thus, compared to the conventional RCD snubber circuit, the efficiency of the RCB snubber circuit of the present embodiment is improved when the load is a light load. The snubber circuit of this embodiment not only has a dramatic improvement in efficiency, according to Average_Efficiency in Table 1 and Table 2, there is also a slight increase on the average efficiency by 0.3% when the load is a heavy load. Therefore, compared to using the power supply of an RCD snubber circuit, using a power supply with the transistor structure of the present invention is more efficient, particularly in a light load condition.

Please refer to FIG. 1B, which is a diagram illustrating a transistor structure according to a second embodiment of the present invention. The transistor structure of the present invention includes a chip package 1 and two pins 2 and 3, wherein the chip package 1 includes a transistor die 11, a capacitor die 13, and a molding compound 12 encapsulating the transistor die 11 and the capacitor die 13. The third bonding pad 113 of the transistor die 11 is electrically connected to a first bonding pad 131 of the capacitor die 13. The pin 2 is electrically connected to a first bonding pad 111 and the second bonding pad 112 of the transistor die 11, and the pin 3 is electrically connected to a second bonding pad 132 of the capacitor die 13. The transistor structure of this embodiment may make the first bonding pad 111 (or the second bond 112) of the transistor die 11 electrically connected to the first bonding pad 131 of the capacitor die 13, may make the pin 2 electrically connected to the second bonding pad 132 of the capacitor die 13, and may make the pin 3 electrically connected to the third bonding pad 113 (not shown) of the transistor die 11. However, this is not meant to be a limitation of the preset invention. Please refer to FIG. 2C, which shows that the transistor die 11 of this embodiment is a BJT die, where the BJT die may be an NPN type BJT die or a PNP type BJT die.

Thus, base and emitter of the BJT of this embodiment are conductive, and the transistor structure has characteristics like fast turn-on, long storage time, switching smoothly, and small base-collector junction capacitance C_{bc} according to at least one junction characteristic between the base and the collector of the BJT die. The transistor structure may be used as a fast diode, and forms a CB snubber circuit by an electrical connection with the capacitor die. Hence, the transistor structure could simplify the process, reduce size, and increase the withstanding voltage when employed on packaging and application circuits. The CB snubber circuit may be connected to an active component or a load (not shown) in parallel, wherein the active component is or is assembled by a Metal Oxide Semiconductor Field Effect Transistor (MOSFET), a diode, a Bipolar Junction Transistor (BJT), an Insulated Gate Bipolar Transistor (IGBT), a Static Induction Transistor (SIT), or a thyristor, and the load is or is assembled by an inductor, a resistor, or a capacitor. For example, the CB snubber circuit is connected to a primary side of a transformer of a switching power supply in parallel and then connected to a MOSFET in series to absorb spikes or noise generated by the active component while the active component is switching at the high frequency. Therefore, the spikes generated by the active component could be reduced and thus the efficiency is improved.

The chip package 1 of the transistor structure of this embodiment may include a resistor die, which is connected between the transistor die 11 and the capacitor die 13. That is to say, the first bonding pad of the resistor die is electrically connected to the first bonding pad 111 or the third bonding pad 113 of the transistor die 11, and the second bonding pad of the resistor die is electrically connected to the first bonding pad 131 (not shown) of the capacitor die 13, and the resistor die is encapsulated by the molding compound 12 to make the transistor structure form a RCB snubber circuit. Thus, the transistor structure could simplify the process, reduce size, and increase the withstanding voltage when employed on packaging and application circuits.

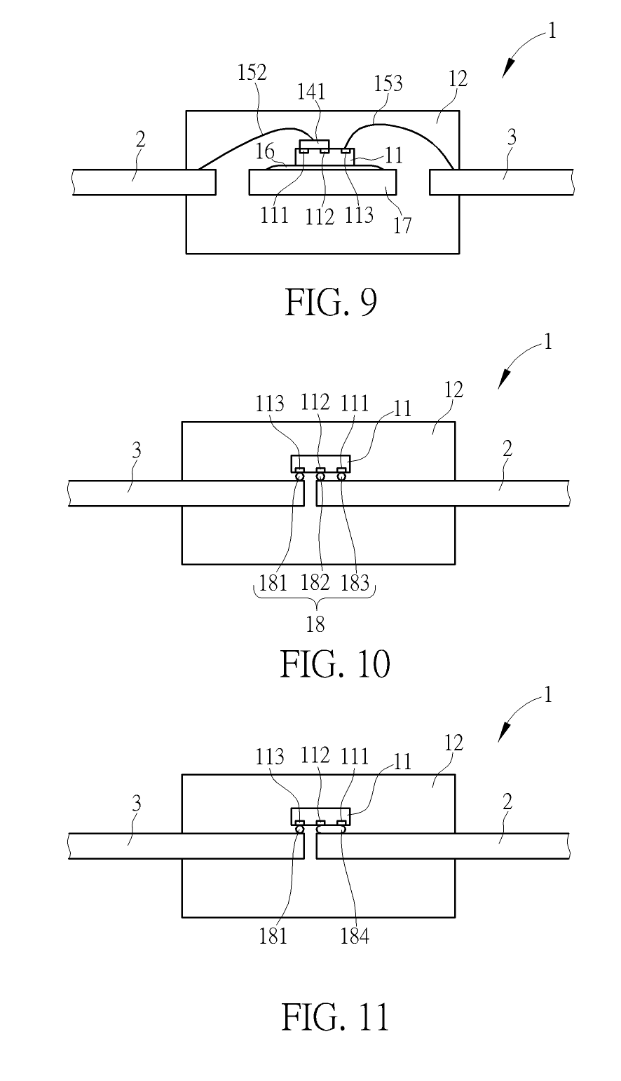

Please refer to FIG. 10, which is a diagram illustrating the transistor structure according to a third embodiment of the present invention. The transistor structure of the present invention includes a chip package 1 and two pins 2 and 3, wherein the chip package 1 includes a transistor die 11, a capacitor die 13, a zener diode die 14, and a molding compound 12 encapsulating the transistor die 11, the capacitor die 13, and the zener diode die 14. The third bonding pad 113 of the transistor die 11 is electrically connected to a first bonding pad 131 of the capacitor die 13 and a first bonding pad 141 of the zener diode die 14. The pin 2 is electrically connected to a first bonding pad 111 and the second bonding pad 112 of the transistor die 11, and the pin 3 is electrically connected to a second bonding pad 132 of the capacitor die 13 and a second bonding pad 142 of the zener diode die 14. The transistor structure of this embodiment may make the first bonding pad 111 and the second bonding pad 112 of the transistor die 11 electrically connected to the first bonding pad 131 of the capacitor die 13 and the first bonding pad 141 of the zener diode die 14, may make the pin 2 electrically connected to the second bonding pad 132 of the capacitor die 13 and the second bonding pad 142 of the zener diode die 14, and may make the pin 3 electrically connected to the third bonding pad 113 of the transistor die 11.

That is to say that, the aforesaid zener diode die 14 is electrically connected to the capacitor die 13 in parallel and then connected to the transistor die 11 in series. However, this is not meant to be a limitation of the preset invention. The second bonding pad 142 of the zener diode die 14 of this embodiment may be electrically connected to the first bonding pad 111 or the third bonding pad 113 of the transistor die 11, that is to say, the zener diode die 14 may be connected to the transistor die 11 in parallel, and then connected to the capacitor die 13 in series. Please refer to FIG. 2D, which shows that the transistor die 11 of this embodiment is a BJT die, where the BJT die may be an NPN type BJT or a PNP type BJT die.

Thus, base and emitter of the BJT of this embodiment are conductive, and the transistor structure has characteristics like fast turn-on, long storage time, switching smoothly, and small base-collector junction capacitance C_{bc} according to at least one junction characteristic between the base and the collector of the BJT die. The transistor structure may be used as a fast diode, and forms a ZCB snubber circuit (as shown in FIG. 14) by electrical connections with the capacitor die and the zener diode die. Hence, the transistor structure could simplify the process, reduce size, and increase the withstanding voltage when employed on packaging and application circuits. The ZCB snubber circuit may be connected to an active component or a load (not shown) in parallel, wherein the active component is or is assembled by a Metal Oxide Semiconductor Field Effect Transistor (MOSFET), a diode, a Bipolar Junction Transistor (BJT), an Insulated Gate Bipolar Transistor (IGBT), a Static Induction Transistor (SIT), or a thyristor, and the load is or is assembled by an inductor, a resistor, or a capacitor. For example, the ZCB snubber circuit is connected to a primary side of a transformer of a switching power supply in parallel and then connected to a MOSFET in series to absorb spikes or noise generated by the active component while the active component is switching at the high frequency. In this way, the spikes generated by the active component could be reduced and thus the efficiency is improved.

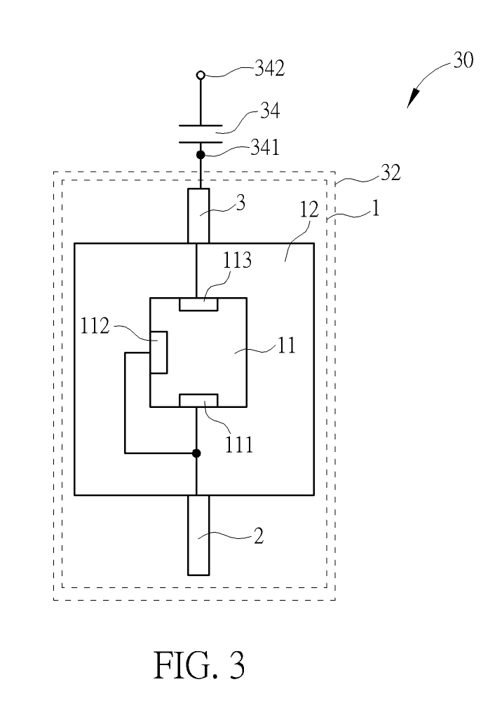

In view of the above, the proposed snubber circuit may be implemented by, but is not limited to, a transistor structure including at least a transistor die and a capacitor die (e.g. the transistor structure shown in FIGS. 1A-1C and 2A-2D, and the snubber circuit shown in FIG. 14), or a transistor structure connected to at least a capacitor (e.g. the snubber circuit shown in FIG. 14). FIG. 3 is a diagram illustrating an exemplary snubber circuit according to an embodiment of the present invention. In this embodiment, the snubber circuit 30 may include a transistor structure 32 and a capacitor 34 coupled to the transistor structure 32. The transistor structure 32 may be implemented by, but is not limited to, the transistor structure shown in FIG. 1A. In other words, the transistor structure 32 may include the chip package 1, the pin 2 and the pin 3, wherein the chip package 1 includes the transistor die 11 and the molding compound 12 encapsulating the transistor die 11, the pin 2 is electrically connected to the first bonding pad 111 and the second bonding pad 112, and the pin 3 is electrically connected to the third bonding pad 113. Additionally, the pin 3 is electrically connected to a terminal 341 of the capacitor 34.

In this embodiment, the first bonding pad 111 and the second bonding pad 112 maybe directly connected so as to implement a two-pin transistor structure used for the snubber circuit 30. The snubber circuit 30 may be connected in parallel to an active component or a load (not shown in FIG. 3), such that the snubber circuit 30 may absorb spikes or noise generated by the active component or the load to the capacitor 34 and transmit energy of the absorbed spikes or the absorbed noise from the capacitor 34 to the active component or the load. By way of example but not limitation, the active component or the load is connected between a terminal 342 of the capacitor 34 and the pin 2, wherein the active component is or is assembled by a Metal Oxide Semiconductor Field Effect Transistor (MOSFET), a diode, a Bipolar Junction Transistor (BJT), an Insulated Gate Bipolar Transistor (IGBT), a Static Induction Transistor (SIT), or a thyristor, and the load is or is assembled by an inductor, a resistor, or a capacitor.

In one implementation, the transistor die 11 maybe implemented by a BJT die (e.g. a NPN type BJT die or a PNP type BJT die), wherein the first bonding pad 111 is an emitter bonding pad, the second bonding pad 112 is a base bonding pad, and the third bonding pad 113 is a collector bonding pad. In a case where the snubber circuit 30 is connected to an active component or a load in parallel, the snubber circuit 30 may use a characteristic of fast turning on and a characteristic of long storage time of the BJT die (the transistor die 11) to absorb spikes or noise generated by the active component or the load to the capacitor 34, and transmit energy of the absorbed spikes or the absorbed noise from the capacitor 34 to the active component or the load. Specifically, based on the characteristic of fast turning on and the characteristic of long storage time of the BJT die, the snubber circuit 30 may transfer leakage energy (the spikes or noise generated by the active component or the load) to the capacitor 34 rapidly and push energy of the capacitor 34 back to a source (e.g. the active component or the load) for energy recycling. As a person skilled in the art should understand the operation of the snubber circuit 30 after reading the above paragraphs directed to FIGS. 1A-1C, 2A-2D and 14, further description is omitted here for brevity.

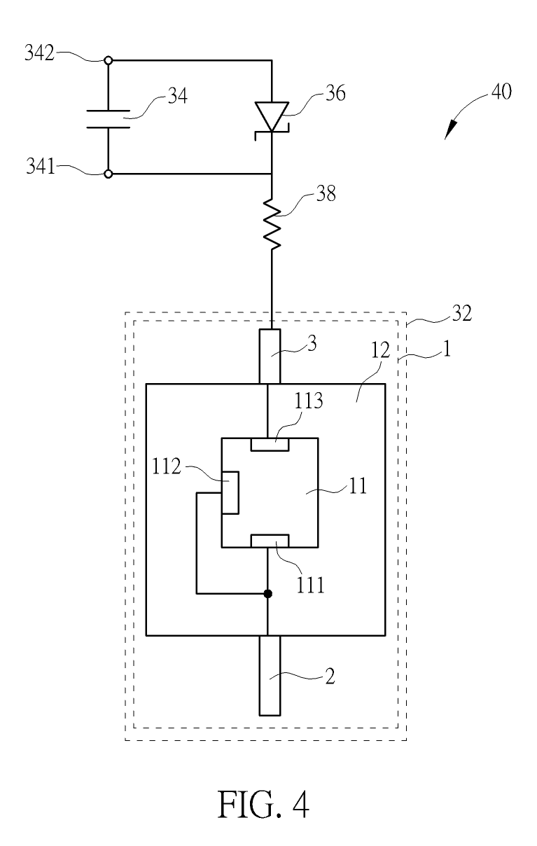

Please note that the above is for illustrative purposes only, and is not meant to be a limitation of the present invention. In an alternative design, the transistor structure 32 may be implemented by the transistor structure shown in FIG. 1B, the transistor structure shown in FIG. 1C, or the transistor structure shown in FIG. 1B including a resistor die connected between the transistor die 11 and the capacitor die 13. In another alternative design, the proposed snubber circuit may include other circuit element(s) connected to the capacitor 34. Please refer to FIG. 4, which is a diagram illustrating an exemplary snubber circuit according to another embodiment of the present invention. The structure of the snubber circuit 40 shown in FIG. 4 is based on the structure of the snubber circuit 30 shown in FIG. 3, and the main difference is that the snubber circuit 40 further includes a zener diode 36 and a resistor 38. In this embodiment, the terminal 341 of the capacitor 34 is further connected to a terminal of the zener diode 36, and the terminal 342 of the capacitor 34 is connected to another terminal of the zener diode 36. The resistor 38 is coupled to the capacitor 34 in series, wherein the resistor 38 is connected between the pin 3 and the capacitor 34.

Please note that the above is for illustrative purposes only, and is not meant to be a limitation of the present invention. In an alternative design, the zener diode 36 is optional. In another alternative design, the resistor 38 is optional. In yet another alternative design where the zener diode 36 is omitted, it is possible to dispose the capacitor 34 between the resistor 38 and the pin 3. Specifically, as long as one of the resistor 38 and the capacitor 34 is connected between one pin of the transistor structure 32 (the pin 2 or the pin 3) and the other of the resistor 38 and the capacitor 34, related modifications and alternatives fall within the scope of the present invention. As a person skilled in the art should understand the operation of the snubber circuit 40 after reading the above paragraphs directed to FIGS. 1A-1C, 2A-2D, 3 and 14, further description is omitted here for brevity.

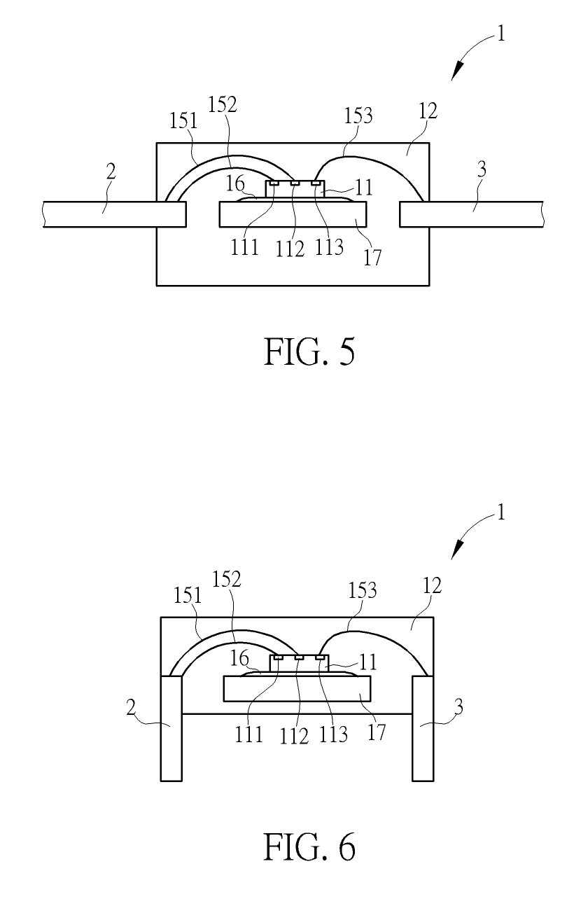

In addition, please refer to FIG. 5-FIG. 9, which are sectional diagrams illustrating the transistor structure electrically connected to pins and bonding pads by way of wire bonding according to embodiments of the present invention. The transistor structure includes a chip package 1 and two pins 2 and 3, wherein the chip package 1 includes a transistor die 11, a molding compound 12, an adhesion layer 16, a die pad 17, and a plurality of bonding wires 151, 152, and 153. The chip package 1 is electrically connected to the pin 2 and 3 by means of bonding wires 151, 152 and 153 electrically connected to the first bonding pad 111, the second bonding pad 112 and the third bonding pad 113. The pins 2 and 3 may set at least a contact (not shown) respectively for electrically connecting the bonding wires 151, 152 and 153. The transistor die 11 is set on the die pad 17 by the adhesion layer 16, and the transistor die 11, the adhesion layer 16, the die pad 17, the bonding wires 151, 152, 153, and part of the pins 2 and 3 are encapsulated by the molding compound 12, therefore part of the pins 2 and 3 are embedded in the molding compound 12, and one end of each of the pins 2 and 3 is outside the molding compound 12. The bonding wires 151, 152, and 153 may be gold wires or made by other conductive material, the adhesion layer 16 may be a silver paste or made by other conductive paste, and the material of the molding compound 12 may be Epoxy or other macromolecule material.

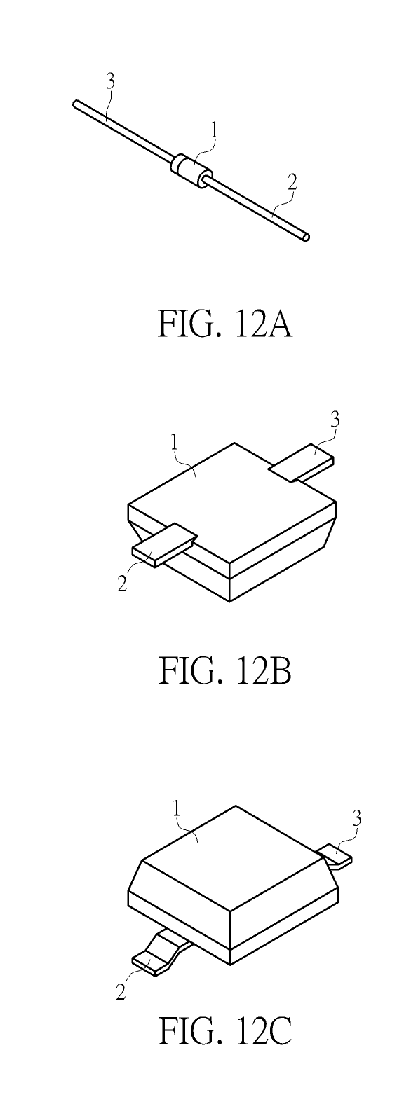

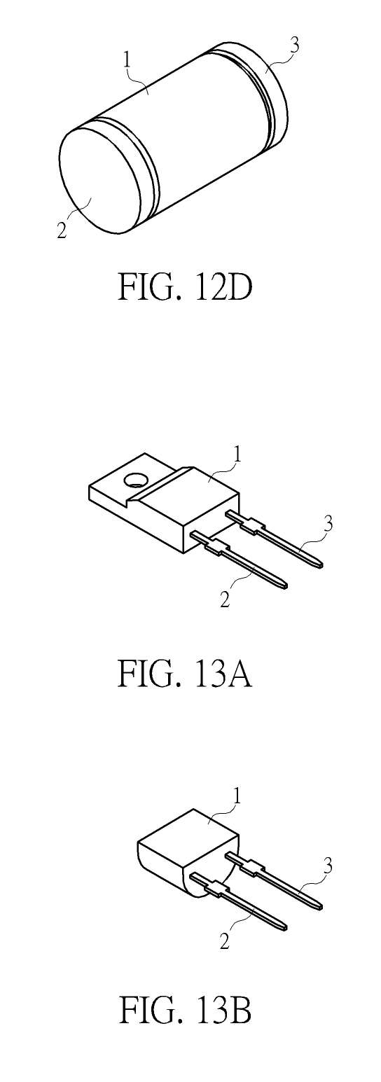

Please refer to FIG. 5, two terminals of the bonding wire 151 of this embodiment are electrically connected to the pin 2 and the second bonding pad 112, and two terminals of the bonding wire 152 are electrically connected to the pin 2 and the first bonding pad 111. Consequently, there is a short circuit between the first bonding pad 111 and the second bonding pad 112. Two terminals of the bonding wire 153 are electrically connected to the pin 3 and the third bonding pad 113. In addition, the pins 2 and 3 are set at two sides of the molding compound 12 and extend horizontally, such that the pins 2 and 3 are parallel to the die pad 17. The appearance of the packaging of the transistor structure may be one of the appearances shown in FIG. 12A-FIG. 12D, wherein the shape of the molding compound 12 may be cylindrical, semicircular, or tablet-shaped, and the pin 153 may be a long lead, a short lead, lead-free, or other contact type.

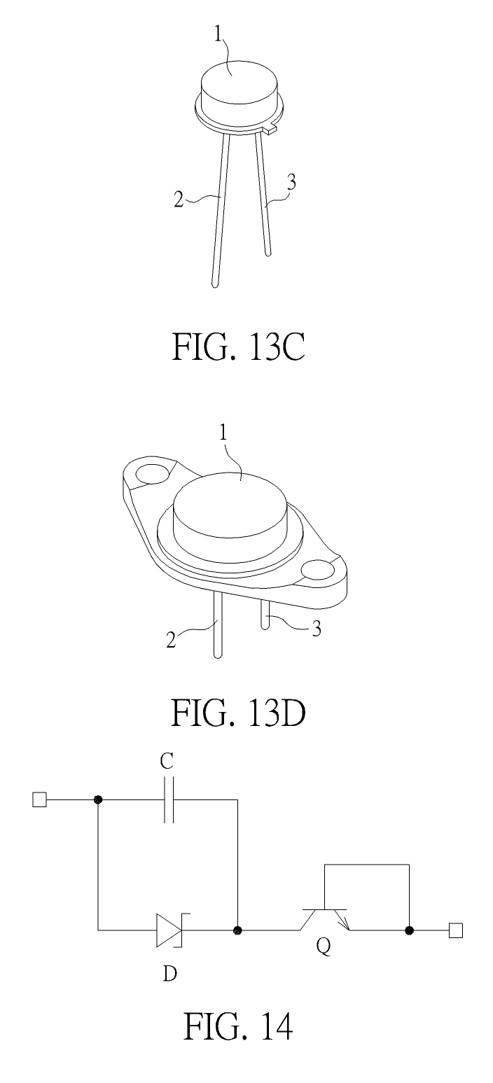

Please refer to FIG. 6. Two terminals of the bonding wire 151 are electrically connected to the pin 2 and the second bonding pad 112, and two terminals of the bonding wire 152 are electrically connected to the pin 2 and the first bonding pad 111. Consequently, there is a short circuit between the first bonding pad 111 and the second bonding pad 112. Two terminals of the bonding wire 153 are electrically connected to the pin 3 and the third bonding pad 113. In addition, the pins 2 and 3 are set at two sides of the molding compound 12 and extend downward, such that the pins 2 and 3 are perpendicular to the die pad 17. The appearance of the packaging of the transistor structure may be one of the appearances shown in FIG. 13A-FIG. 13D, wherein the shape of the molding compound 12 may be cylindrical, semicircular, or tablet-shaped, and the pin 153 may be a long lead, a short lead, lead-free, or other contact type.

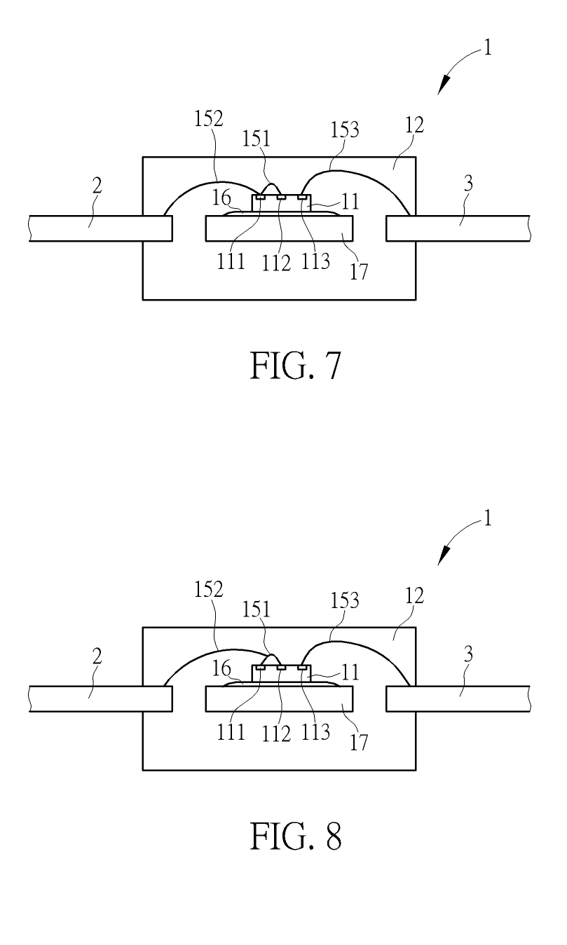

Please refer to FIG. 7. Two terminals of the bonding wire 151 are electrically connected to the first bonding pad 111 and the second bonding pad 112, resulting in a short circuit between the first bonding pad 111 and the second bonding pad 112. Two terminals of the bonding wire 152 are electrically connected to the pin 2 and the first bonding pad 111, and two terminals of the bonding wire 153 are electrically connected to the pin 3 and the third bonding pad 113. In addition, the pins 2 and 3 are set at two sides of the molding compound 12 and extend horizontally, such that the pins 2 and 3 are parallel to the die pad 17.

Please refer to FIG. 8. Two terminals of the bonding wire 151 are electrically connected to the first bonding pad 111 and the second bonding pad 112, resulting in a short circuit between the first bonding pad 111 and the second bonding pad 112. Two terminals of the bonding wire 152 are electrically connected to the pin 2 and the bonding wire 151, and two terminals of the bonding wire 153 are electrically connected to the pin 3 and the third bonding pad 113.

Please refer to FIG. 9. This embodiment has a short circuit between the first bonding pad 111 and the second bonding pad 112 by a fourth bonding pad 114 electrically connected to the first bonding pad 111 and the second bonding pad 112. Two terminals of the bonding wire 152 are electrically connected to the pin 2 and the fourth bonding pad 114, and two terminals of the bonding wire 153 are electrically connected to the pin 3 and the third bonding pad 113.

Please refer to FIG. 10 in conjunction with FIG. 11. FIG. 10 and FIG. 11 are sectional diagrams illustrating the transistor structure electrically connected to pins and bonding pads by way of flip chip bonding according to embodiments of the present invention. The transistor structure includes a chip package 1 and two pins 2 and 3, wherein the chip package 1 includes a transistor die 11, a molding compound 12, and a bonding material 18. The bonding material 18 is first formed on the surface of a first bonding pad 111 and a second bonding pad 112. Next, the transistor die 11 is flipped over, and the first bonding pad 111, the second bonding pad 112, and the third bonding pad 113 are connected to the pin 2 and 3 through the bonding material 18, thereby making the transistor die 11 electrically connected to the pins 2 and 3. The pins 2 and 3 may set at least a contact (not shown) respectively for electrically connecting the bonding material 18. The transistor die 11, the bonding material 18, and part of the pins 2 and 3 are encapsulated by the molding compound 12. Therefore, part of the pins 2 and 3 are embedded in the molding compound 12, and one end of each of the pins 2 and 3 is outside the molding compound 12. The material of the bonding material 18 may be tin or other metal material.

As shown in FIG. 10, the bonding material 18 of this embodiment includes a first bonding material 181, a second bonding material 182, and a third bonding material 183. The first bonding material 181 electrically connects the pin 2 to the third bonding pad 113. The second bonding material 182 and the third bonding material 183 electrically connect the pin 3 to the first bonding pad 111 and the second bonding pad 112. Consequently, there is a short circuit between the first bonding pad 111 and the second bonding pad 112.

As shown in FIG. 11, the bonding material 18 of this embodiment includes a first bonding material 181 and a fourth bonding material 184. The first bonding material 181 electrically connects the pin 2 to the third bonding pad 113. The fourth bonding material 184 electrically connects the pin 3 to the first bonding pad 111 and the second bonding pad 112. Consequently, there is a short circuit between the first bonding pad 111 and the second bonding pad 112.

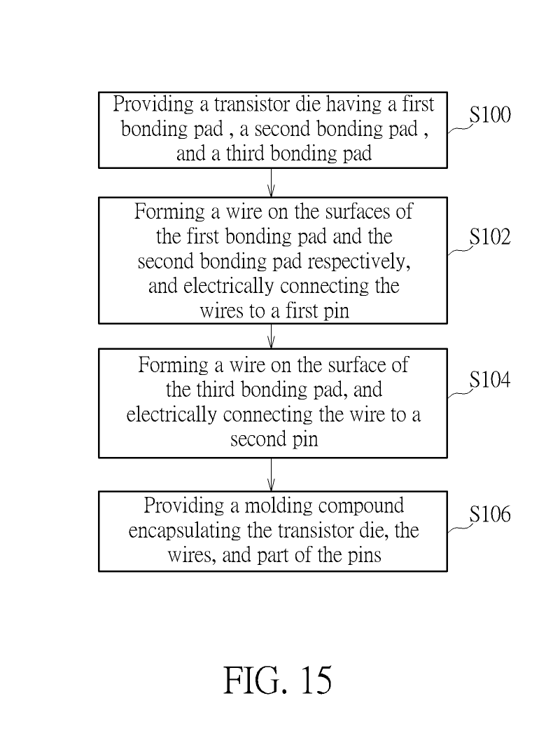

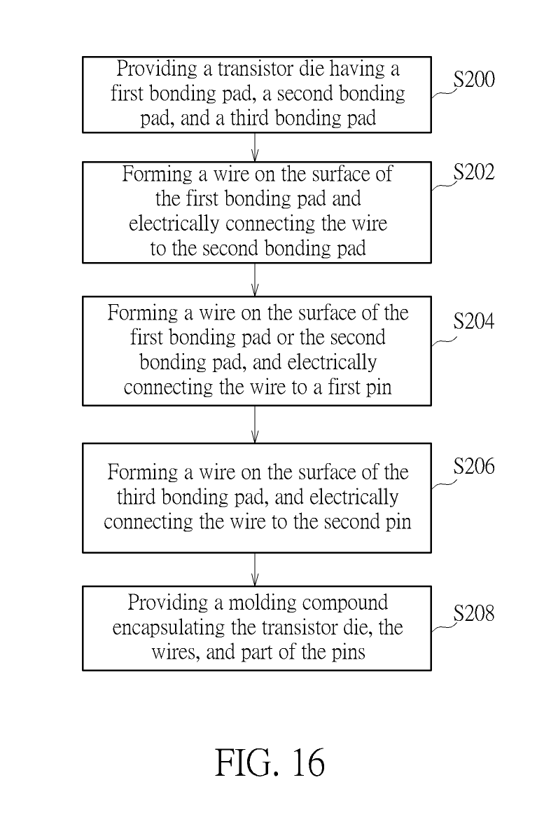

Please refer to FIG. 4 in conjunction with FIG. 15. FIG. 15 is a flowchart of a transistor packaging method according to a first embodiment of the present invention. The transistor packaging method includes following steps: first, providing a transistor die 11 having a first bonding pad 111, a second bonding pad 112, and a third bonding pad 113 (S100); then, forming a bonding wire 151 and a bonding wire 152 on the surfaces of the first bonding pad 111 and the second bonding pad 112, respectively, and electrically connecting the bonding wires 151, 152 to a first pin 2 (S102); then, forming a bonding wire 153 on the surface of the third bonding pad 113, and electrically connecting the bonding wire 153 to a second pin 3 (S104); finally, providing a molding compound 12 encapsulating the transistor die 11, the bonding wires 151-153, and part of the pins 2 and 3 (S106).

Please refer to FIG. 7 in conjunction with FIG. 16. FIG. 16 is a flowchart of a transistor packaging method according to a second embodiment of the present invention. The transistor packaging method includes following steps: first, providing a transistor die 11 having a first bonding pad 111, a second bonding pad 112, and a third bonding pad 113 (S200); then, forming a bonding wire 151 on the surface of the first bonding pad 111 and electrically connecting the bonding wire 151 to the second bonding pad 112 (S202); then, forming a bonding wire 152 on the surface of the first bonding pad 111 or the second bonding pad 112, and electrically connecting the bonding wire 152 to a first pin 2 (S204); then, forming a bonding wire 153 on the surface of the third bonding pad 113 and electrically connecting the wire 153 to a second pin 3 (S206); finally, providing a molding compound 12 encapsulating the transistor die 11, the wires 151-153, and part of the pins 2 and 3 (S208).

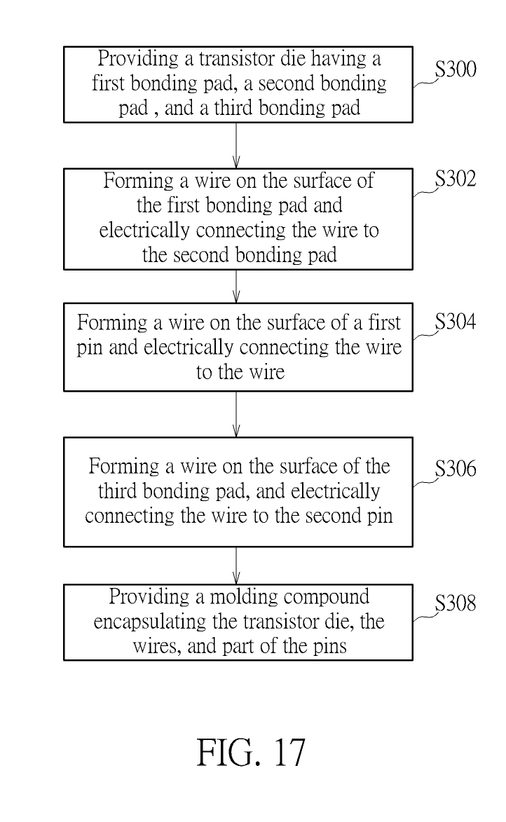

Please refer to FIG. 8 in conjunction with FIG. 17. FIG. 17 is a flowchart of a transistor packaging method according to a third embodiment of the present invention. The transistor packaging method includes following steps: first, providing a transistor die 11 having a first bonding pad 111, a second bonding pad 112, and a third bonding pad 113 (S300); then, forming a bonding wire 151 on the surfaces of the first bonding pad 111 and electrically connecting the bonding wire 151 to the second bonding pad 112 (S302); then, forming a bonding wire 152 on the surface of a first pin 2 and electrically connecting the bonding wire 152 to the bonding wire 151 (S304); then, forming a bonding wire 153 on the surface of the third bonding pad 113 and electrically connecting the bonding wire 153 to a second pin 3 (S306); finally, providing a molding compound 12 encapsulating the transistor die 11, the bonding wires 151-153, and part of the pins 2 and 3 (S308).

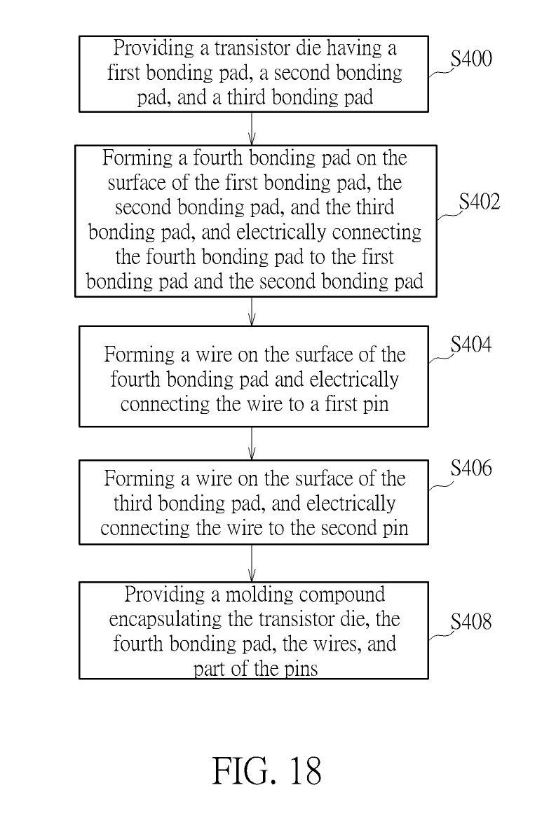

Please refer to FIG. 9 in conjunction with FIG. 18. FIG. 18 is a flowchart of a transistor packaging method according to a second embodiment of the present invention. The transistor packaging method includes following steps: first, providing a transistor die 11 having a first bonding pad 111, a second bonding pad 112, and a third bonding pad 113 (S400); then, forming a fourth bonding pad 114 on the surface of the first bonding pad 111, the second bonding pad 112, and the third bonding pad 113, and electrically connecting the fourth bonding pad 114 to the first bonding pad 111 and the second bonding pad 112 (S402); then, forming a bonding wire 152 on the surface of the fourth bonding pad 114 and electrically connecting the bonding wire 152 to a first pin 2 (S404); then, forming a bonding wire 153 on the surface of the third bonding pad 113 and electrically connecting the bonding wire 153 to a second pin 3 (S406); finally, providing a molding compound 12 encapsulating the transistor die 11, the fourth bonding pad 114, the bonding wires 152 and 153, and part of the pins 2 and (S408).

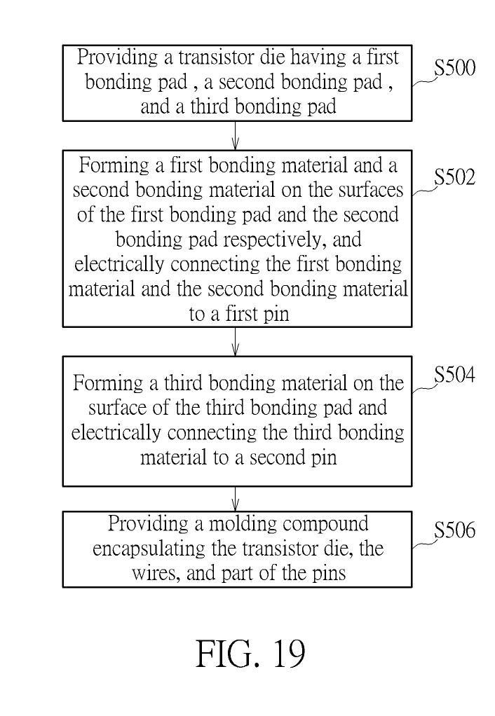

Please refer to FIG. 10 in conjunction with FIG. 19. FIG. 19 is a flowchart of a transistor packaging method according to a fifth embodiment of the present invention. The transistor packaging method includes following steps: first, providing a transistor die 11 having a first bonding pad 111, a second bonding pad 112, and a third bonding pad 113 (S500); then, forming a first bonding material 182 and a second bonding material 183 on the surfaces of the first bonding pad 111 and the second bonding pad 112, respectively, and electrically connecting the first bonding material 182 and the second bonding material 183 to a first pin 2 (S502); then, forming a third bonding material 183 on the surface of the third bonding pad 113 and electrically connecting the third bonding material 183 to a second pin (S504); finally, providing a molding compound 12 encapsulating the transistor die 11, the bonding material 18, and part of the pins 2 and 3 (S506).

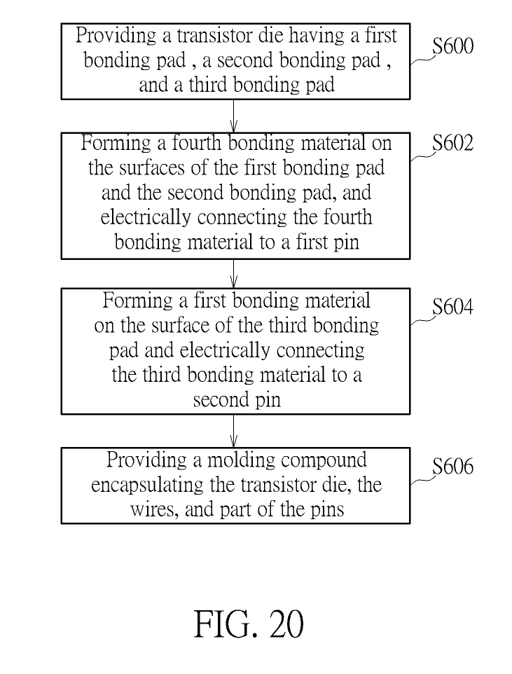

Please refer to FIG. 11 in conjunction with FIG. 20. FIG. 20 is a flowchart of a transistor packaging method according to a second embodiment of the present invention. The transistor packaging method includes following steps: first, providing a transistor die 11 having a first bonding pad 111, a second bonding pad 112, and a third bonding pad 113 (S600); then, forming a fourth bonding material 184 on the surfaces of the first bonding pad 111 and the second bonding pad 112, respectively, and electrically connecting the fourth bonding material 184 to a first pin 2 (S602); then, forming a first bonding material 181 on the surface of the third bonding pad 113 and electrically connecting the first bonding material 181 to a second pin (S604); finally, providing a molding compound 12 encapsulating the transistor die 11, the bonding material 181 and 184, and part of the pins 2 and (S606).

The transistor dies of the aforesaid embodiments of the transistor packaging method are BJT dies.

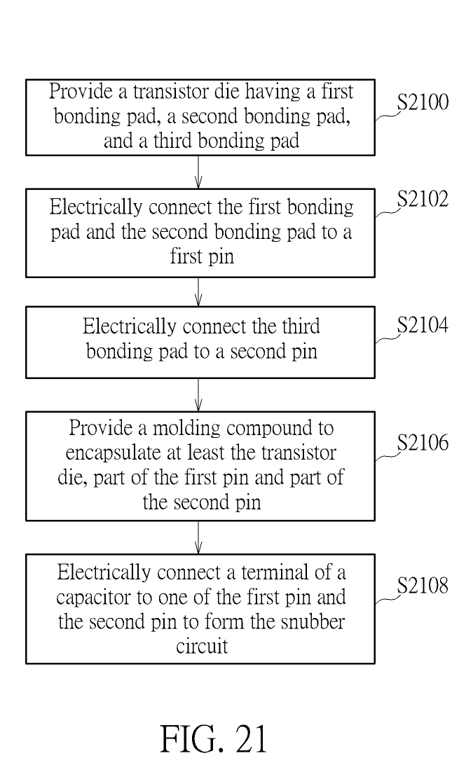

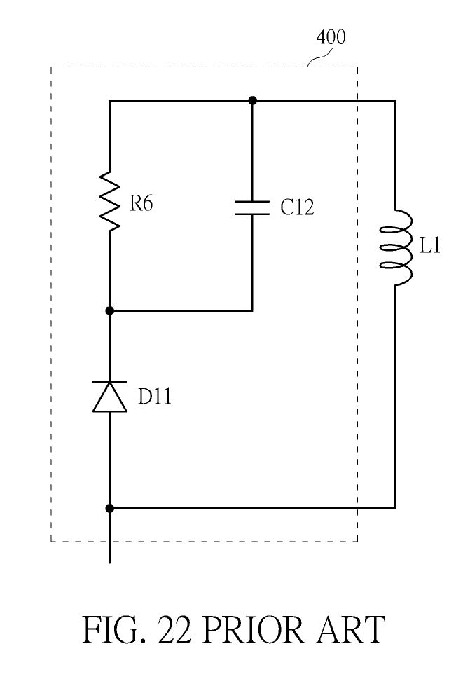

In view of the above, the proposed method for forming a snubber circuit may be summarized in FIG. 21. FIG. 21 is a flow chart of an exemplary method for forming a snubber circuit according to an embodiment of the present invention. Provided that the result is substantially the same, the steps are not required to be executed in the exact order shown in FIG. 21. The method shown in FIG. 21 may be summarized below.

Step S2100: Provide a transistor die having a first bonding pad, a second bonding pad, and a third bonding pad. For example, the transistor die 11 shown in FIG. 1A/1B/1C may be provided.

Step S2102: Electrically connect the first bonding pad and the second bonding pad to a first pin. For example, the first bonding pad 111 and the second bonding pad 112 shown in FIG. 1A/1B/1C may be connected to the same pin.

Step S2104: Electrically connect the third bonding pad to a second pin. For example, the third bonding pad 113 shown in FIG. 1A/1B/1C may be connected to another pin different from the pin which the first bonding pad 111 is connected to.

Step S2106: Provide a molding compound to encapsulate at least the transistor die, part of the first pin and part of the second pin. For example, in the embodiment shown in FIG. 1A/1B/1C, the molding compound 12 is provided to encapsulate at least the transistor die 11, part of the pin 2 and part of the pin 3.

Step s2108: Electrically connect a terminal of a capacitor to one of the first pin and the second pin to form the snubber circuit. For example, in the embodiment shown in FIG. 3/4, the terminal 341 is electrically connected to the pin 3 to form the snubber circuit 30/40.

Please note that steps S2100-S2108 may be implemented by the transistor packaging methods shown in FIGS. 15-20. As a person skilled in the art should understand the operation of each step of the method shown in FIG. 21 after reading the above paragraphs directed to FIGS. 1A-20, further description is omitted here for brevity.

In summary, according to the above disclosed embodiments, the present invention actually can achieve the desired objective by using one pin electrically connected to a first bonding pad and a second bonding pad of the transistor die, and another pin electrically connected to a third bonding pad of the transistor die. The transistor structure maybe employed in a snubber circuit, or the snubber circuit may be encapsulated in the two-pin transistor structure to connect an active component or a load in parallel to absorb spikes or noise generated by the active component while the active component is switching at a high frequency. Therefore, the packaging of the transistor structure could simplify the process, reduce size, increase the withstanding voltage, and improve the efficiency and reduce the spike voltage of the power supply of the snubber circuit. The present invention indeed has practical value undoubtedly, and therefore has the utility which is new and non-obvious over the conventional designs.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A snubber circuit, comprising:
a transistor structure, comprising:
a chip package, comprising a transistor die and a molding compound encapsulating the transistor die; and
two pins, wherein a first pin is electrically connected to a first bonding pad and a second bonding pad of the transistor die, and a second pin is electrically connected to a third bonding pad of the transistor die; and
a first capacitor, wherein the first pin or the second pin of the transistor structure is electrically connected to a terminal of the first capacitor.

2. The snubber circuit of claim 1, wherein the snubber circuit is connected to an active component or a load in parallel; and the snubber circuit absorbs spikes or noise generated by the active component or the load to the first capacitor, and transmits energy of the absorbed spikes or the absorbed noise from the first capacitor to the active component or the load.

3. The transistor structure of claim 2, wherein the active component is or is assembled by a Metal Oxide Semiconductor Field Effect Transistor (MOSFET), a diode, a Bipolar Junction Transistor (BJT), an Insulated Gate Bipolar Transistor (IGBT), a Static Induction Transistor (SIT), or a thyristor; and the load is or is assembled by an inductor, a resistor, or a second capacitor.

4. The snubber circuit of claim 1, wherein the first bonding pad and the second bonding pad are directly connected.

5. The snubber circuit of claim 1, wherein the transistor die is a Bipolar Junction Transistor (BJT) die.

6. The snubber circuit of claim 5, wherein the first bonding pad of the transistor die is an emitter bonding pad, the second bonding pad is a base bonding pad, and the third bonding pad is a collector bonding pad.

7. The snubber circuit of claim 5, wherein the snubber circuit is connected to an active component or a load in parallel; and the snubber circuit uses a characteristic of fast turning on and a characteristic of long storage time of the BJT die to absorb spikes or noise generated by the active component or the load to the first capacitor, and transmit energy of the absorbed spikes or the absorbed noise from the first capacitor to the active component or the load.

8. The snubber circuit of claim 1, further comprising:
a zener diode, wherein the terminal of the first capacitor is further connected to a terminal of a zener diode, and another terminal of the first capacitor is connected to another terminal of the zener diode.

9. The snubber circuit of claim 1, further comprising:
a resistor, coupled to the first capacitor in series, wherein one of the resistor and the first capacitor is connected between the first pin or the second pin of the transistor structure and the other of the resistor and the first capacitor.

10. The snubber circuit of claim 1, wherein the first bonding pad, the second bonding pad, and the third bonding pad are connected to the two pins through wire bonding.

11. The snubber circuit of claim 10, wherein the wire bonding includes three bonding wires connected to the two pins respectively.

12. The snubber circuit of claim 10, wherein the first bonding pad and the second bonding pad are electrically connected to each other, one of the first pin and the second pin is connected to the first bonding pad or the second bonding pad through a first bonding wire, and the third bonding pad is connected to another of the first pin and the second pin through a second bonding wire.

13. The snubber circuit of claim 10, wherein the first bonding pad is electrically connected to the second bonding pad through a bonding wire or a bonding material.

14. The snubber circuit of claim 1, wherein the chip package further comprises a die pad, and the transistor die is set on the die pad by an adhesion layer.

15. The snubber circuit of claim 1, wherein the first bonding pad, the second bonding pad, and the third bonding pad are electrically connected to the two pins through flip chip bonding.
